(19) United States
(12) Patent Application Publication
(10) Pub. No.: US 2026/0011698 A1
(43) Pub. Date: Jan. 8, 2026

(54) ELECTRONIC STRUCTURE, ELECTRONIC PACKAGE AND MANUFACTURING METHOD THEREOF

(71) Applicant: SILICONWARE PRECISION INDUSTRIES CO., LTD., Taichung City (TW)

(72) Inventors: Jui-Cheng LIN, Taichung City (TW); Chi-Ching HO, Taichung City (TW); Chao-Chiang PU, Taichung City (TW); Yi-Min FU, Taichung City (TW); Chiu-Ling CHEN, Taichung City (TW)

(21) Appl. No.: 18/920,334

(22) Filed: Oct. 18, 2024

(30) Foreign Application Priority Data
Jul. 5, 2024 (TW) 113125350

(51) Int. Cl. H01L 25/10; H01L 23/00; H01L 23/31; H01L 23/498; H01L 23/538; H01L 25/00

(52) U.S. Cl. CPC H01L 25/105; H01L 23/3107; H01L 23/49816; H01L 23/538; H01L 24/24; H01L 25/50; H01L 24/16; H01L 24/32; H01L 24/73; H01L 2224/16227; H01L 2224/24146; H01L 2224/32155; H01L 2224/73204; H01L 2225/1041

(57) ABSTRACT

An electronic structure, an electronic package and a manufacturing method thereof are provided, in which a carrier and an adhesive layer are used to support or fix the electronic structure and the electronic package, and double carriers are used to support or fix the electronic structure and the electronic package, thereby avoiding the warpage problem of the electronic structure and the electronic package.

### CROSS-REFERENCE TO RELATED APPLICATIONS

The present application is based upon and claims the right of priority to TW patent application Ser. No. 11/312,5350, filed Jul. 5, 2024, the disclosure of which is hereby incorporated by reference herein in its entirety for all purposes.

### BACKGROUND

### 1. Technical Field

The present disclosure relates to an electronic packaging technology, and more particularly, to an electronic structure, an electronic package and a manufacturing method thereof.

### 2. Description of Related Art

FIG. 1A to FIG. 1D are schematic cross-sectional views illustrating a manufacturing method of a conventional semiconductor package.

First, as shown in FIG. 1A, a carrier 16 and a package structure 19 are provided, and a lower side of the package structure 19 is disposed on an upper side of the carrier 16.

In detail, a bonding layer 161 is formed as a sacrificial release layer on the upper side of the carrier 16 by coating. The package structure 19 is disposed on the bonding layer 161.

The package structure 19 includes a first insulating layer 111, at least one first semiconductor chip 12, an adhesive layer 121, conductive components 123, a second insulating layer 124, conductive pillars 112, a first encapsulant 113, a redistribution layer 13, a second semiconductor chip 14, first conductive bumps 142, an underfill 143, and a second encapsulant 144. The redistribution layer 13 includes an insulating layer 131 and a circuit layer 132 bonded to the insulating layer 131.

A plurality of electrode pads 122 are disposed on an active surface at an upper side of the first semiconductor chip 12. The plurality of conductive components 123 are coupled to the plurality of electrode pads 122. The second insulating layer 124 is formed on the active surface of each first semiconductor chip 12 and is located around the plurality of conductive components 123. An inactive surface at a lower side of the first semiconductor chip 12 is bonded to the first insulating layer 111 via the adhesive layer 121. A plurality of conductive pillars 112 are disposed around the first semiconductor chip 12. The first encapsulant 113 covers the plurality of conductive pillars 112, the first semiconductor chip 12, the adhesive layer 121 and the second insulating layer 124. The redistribution layer 13 is formed on the upper sides of the first semiconductor chip 12, the plurality of conductive components 123, the second insulating layer 124, the plurality of conductive pillars 112 and the first encapsulant 113.

The second semiconductor chip 14 has an inactive surface at an upper side and an active surface at a lower side, and the active surface has a plurality of electrode pads 141 to be bonded to a plurality of first conductive bumps 142. The second semiconductor chip 14 is flip-chip bonded to an upper side of the redistribution layer 13 via the electrode pads 141 and the first conductive bumps 142. The underfill 143 covers the plurality of first conductive bumps 142. The second encapsulant 144 is disposed on the upper side of the redistribution layer 13 and covers the second semiconductor chip 14 and the underfill 143.

As shown in FIG. 1B, the carrier 16 and the bonding layer 161 are removed, the package structure 19 is flipped, and then an under bump metallurgy (UBM) layer 151 and a plurality of second conductive bumps 152 are formed on an upper side of the package structure 19.

As shown in FIG. 1C, the package structure 19 is ground to remove part of the second encapsulant 144 and the second semiconductor chip 14, and to expose the second semiconductor chip 14.

The conventional semiconductor structure 1 shown in FIG. 1A to FIG. 1C is a large-layout semiconductor structure. In other words, the semiconductor structure 1 includes a plurality of package structures 19, and the manufacturing method shown in FIG. 1A to FIG. 1C is a method in which the plurality of package structures 19 are manufactured simultaneously. After the manufacturing method shown in FIG. 1A to FIG. 1C, the large-layout semiconductor structure 1 can be cut into a plurality of individual semiconductor packages 100, as shown in FIG. 1D.

However, in the application of a central processing unit (CPU) of a thin notebook computer, its height limitation limits the conventional semiconductor package 100 to an extremely thin thickness, wherein a large amount of warpage is likely to occur after the carrier 16 is removed, thereby resulting in difficulties in subsequent formation and grinding operations of the second conductive bumps 152.

Therefore, how to avoid the deficiencies of the prior art has become an urgent issue to be solved.

### SUMMARY

In view of the various deficiencies of the prior art, the present disclosure provides an electronic structure, which comprises: a package module defined with a wiring section and a component section disposed on the wiring section, wherein the wiring section has a first side and a second side opposite to the first side and includes a first electronic component and a redistribution layer, wherein the component section has a first side and a second side opposite to the first side and includes a second electronic component, and the second side of the component section is disposed on the first side of the wiring section, and wherein, at the same time, the redistribution layer is electrically connected to the first electronic component and the second electronic component; and a component-side carrier having a first side and a second side opposite to the first side, wherein the second side of the component-side carrier is disposed on the first side of the component section.

The present disclosure further provides an electronic package, which comprises: a package module defined with a wiring section and a component section disposed on the wiring section, wherein the wiring section has a first side and a second side opposite to the first side and includes a first electronic component and a redistribution layer, wherein the component section has a first side and a second side opposite to the first side and includes a second electronic component, and the second side of the component section is disposed on the first side of the wiring section, and wherein, at the same time, the redistribution layer is electrically connected to the first electronic component and the second electronic component; conductive bumps disposed on the second side of the wiring section; and an adhesive layer formed on the second side of the wiring section to cover the conductive bumps.

The present disclosure also provides a method for manufacturing an electronic package, which comprises: providing a wiring-side carrier and a package module, wherein the package module is defined a wiring section and a component section, each of the wiring-side carrier, the wiring section, and the component section has a first side and a second side opposite to the first side, and the second side of the component section is disposed on the first side of the wiring section; disposing the package module on the first side of the wiring-side carrier via the second side of the wiring section; and disposing a component-side carrier having a first side and a second side opposite to the first side on the first side of the component section via the second side of the component-side carrier.

In the present disclosure, a carrier and an adhesive layer are used to support or fix the electronic structure and the electronic package, and double carriers are used to support or fix the electronic structure and the electronic package, thereby avoiding the warpage problem of the electronic structure and the electronic package.

### BRIEF DESCRIPTION OF THE DRAWINGS

FIG. 1A to FIG. 1D are schematic cross-sectional views illustrating a manufacturing method of a conventional semiconductor package.

FIG. 2A to FIG. 2E are schematic cross-sectional views illustrating a manufacturing method of an electronic package according to a first embodiment of the present disclosure.

FIG. 3A and FIG. 3B are schematic cross-sectional views illustrating a manufacturing method of an electronic package according to a second embodiment the present disclosure.

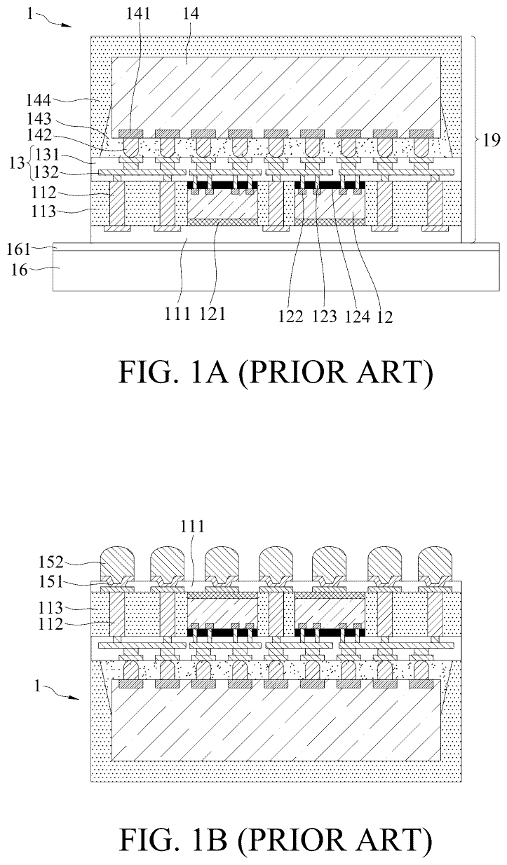

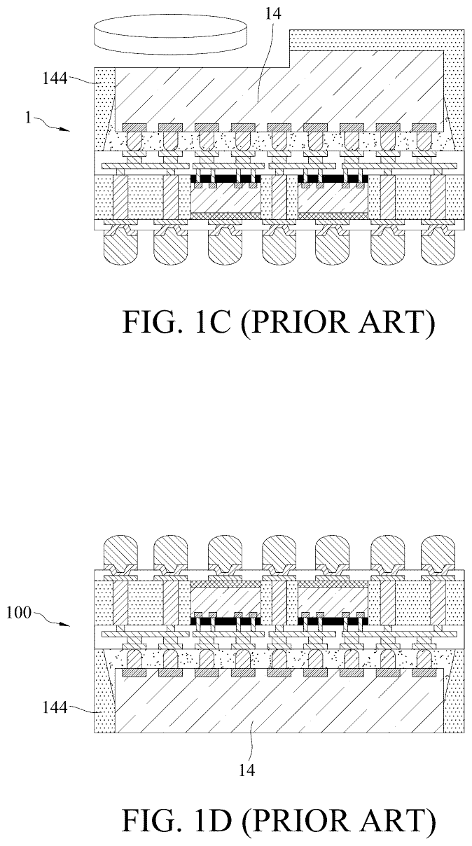

### DETAILED DESCRIPTION

The following describes the implementation of the present disclosure with examples. Those skilled in the art can easily understand other advantages and effects of the present disclosure from the contents disclosed in this specification.

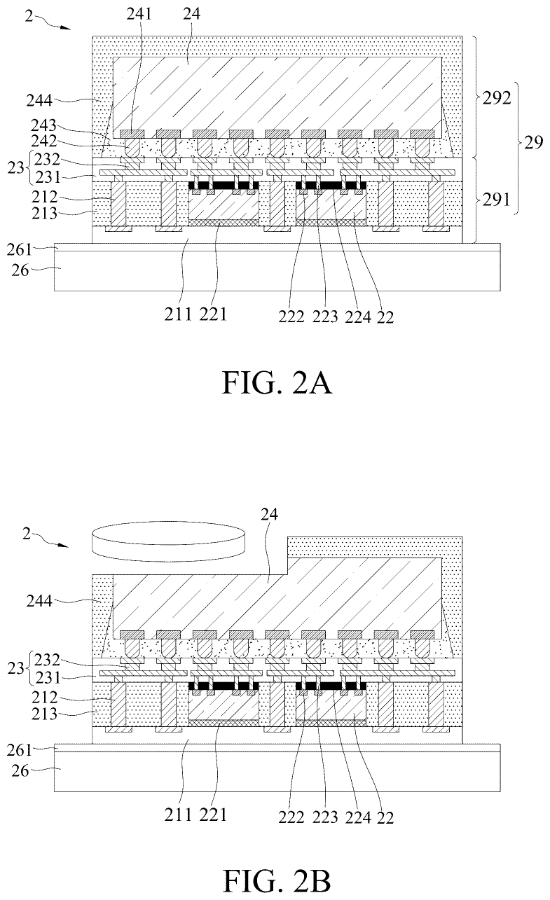

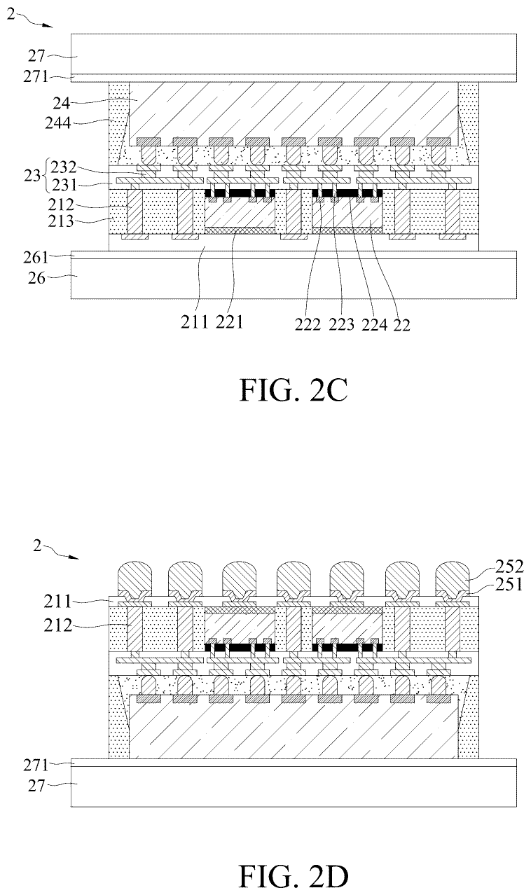

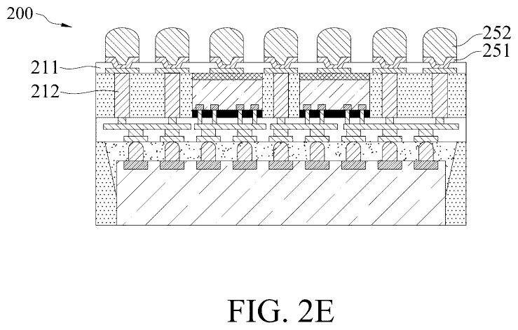

FIG. 2A to FIG. 2E are schematic cross-sectional views illustrating a manufacturing method of an electronic package according to a first embodiment of the present disclosure.

First, as shown in FIG. 2A, a wiring-side carrier 26 and a package module 29 are provided, wherein the package module 29 is defined with a wiring section 291 and a component section 292, the component section 292 is disposed on the wiring section 291, and a thickness of the component section 292 is greater than that of the wiring section 291.

All elements in FIG. 2A to FIG. 2E, such as the package module 29, the wiring section 291, the component section 292, the wiring-side carrier 26, and other elements, all have a first side and a second side opposite to the first side. The first side refers to the upper side in FIG. 2A to FIG. 2C and the lower side in FIG. 2D and FIG. 2E. Correspondingly, the second side refers to the lower side in FIG. 2A to FIG. 2C and the upper side in FIG. 2D and FIG. 2E. The second side of the component section 292 is disposed on the first side of the wiring section 291, and the entire package module 29 is disposed on the first side of the wiring-side carrier 26 via the second side of the wiring section 291.

In detail, a wiring-side bonding layer 261 having a release film or other adhesive film is formed on the first side of the wiring-side carrier 26 by, for example, coating, wherein the wiring-side bonding layer 261 serves as a sacrificial release layer. The package module 29 is disposed on the first side of the wiring-side bonding layer 261 via the second side of the wiring section 291.

The wiring section 291 of the package module 29 includes a first insulating layer 211, at least one first electronic component 22 (e.g., two first electronic components 22 shown in FIGS. 2A-2E), an adhesive material 221, a plurality of conductive components 223, a second insulating layer 224, a plurality of conductive pillars 212, a first packaging layer 213, and a redistribution layer 23.

The first insulating layer 211 may be made of polybenzoxazole (PBO), polyimide (PI), prepreg (PP) or other dielectric materials.

Each first electronic component 22 may be an active component, a passive component or a combination thereof, and the active component is, for example, a semiconductor chip, and the passive component is, for example, a resistor, a capacitor, and an inductor.

The conductive component 223 can be made of copper or other conductive materials, and the second insulating layer 224 may be made of polybenzoxazole (PBO), polyimide (PI), prepreg (PP) or other dielectric materials.

The conductive pillars 212 may be made of copper or other conductive materials.

The first coating layer 213 is made of an insulating material, such as polyimide (PI), epoxy resin (epoxy) encapsulant or encapsulating material. The first packaging layer 213 can be formed by molding, lamination or coating.

The redistribution layer 23 includes at least one insulating layer 231 and at least one circuit layer 232 bonded to the insulating layer 231. The circuit layer 232 can be made of copper or other conductive materials, and the insulating layer 231 may be made of polybenzoxazole (PBO), polyimide (PI), prepreg (PP) or other dielectric materials.

A plurality of electrode pads 222 are disposed on the active surface at the first side of each first electronic component 22. The plurality of conductive components 223 are bonded to the plurality of electrode pads 222. The second insulating layer 224 is formed on the active surface of each first electronic component 22 and is formed around the conductive components 223. The inactive surface on the second side of each first electronic component 22 is bonded to the first side of the first insulating layer 211 via the adhesive material 221. The conductive pillars 212 are disposed on the first side of the first insulating layer 211 and around the first electronic component 22. The first packaging layer 213 covers the conductive pillars 212, the first electronic component 22, the adhesive material 221 and the second insulating layer 224. The redistribution layer 23 is formed on the first sides of the first electronic component 22, the conductive components 223, the second insulating layer 224, the conductive pillars 212 and the first packaging layer 213.

The component section 292 of the package module 29 includes at least one second electronic component 24, a plurality of first conductive bumps 242, an underfill 243, and a second packaging layer 244. The underfill 243 covers the first conductive bumps 242. The second packaging layer 244 is formed on the first side of the redistribution layer 23 and covers the second electronic component 24 and the underfill 243.

The second electronic component 24 can be an active component, a passive component, or a combination thereof, and the active component is, for example, a semiconductor chip, and the passive component is, for example, a resistor, a capacitor, and an inductor. The second electronic component 24 has an inactive surface on a first side and an active surface on a second side. The active surface has a plurality of electrode pads 241 to be bonded to a plurality of first conductive bumps 242.

Each of the first conductive bumps 242 may be formed of solder material or a conductive metal material. The second electronic component 24 is bonded to the first side of the redistribution layer 23 via the electrode pads 241 on the active surface of the second electronic component 24 and the first conductive bumps 242 in a flip-chip manner, so as to be electrically connected to the circuit layer 232 of the redistribution layer 23. For example, the underfill 243 can be used to cover the plurality of first conductive bumps 242.

The second packaging layer 244 is made of an insulating material, such as polyimide (PI), epoxy resin (epoxy) encapsulant or encapsulating material. The second packaging layer 244 can also be formed by molding, lamination or coating.

The conductive pillars 212 are electrically connected to the circuit layer 232 of the redistribution layer 23. The circuit layer 232 of the redistribution layer 23 is electrically connected to each of the first electronic components 22 via the conductive components 223 and the electrode pads 222 of the first electronic component 22. In addition, the circuit layer 232 of the redistribution layer 23 is electrically connected to the second electronic component 24 via the first conductive bumps 242 and the electrode pads 241 of the second electronic component 24. Thereby, the conductive pillars 212 are electrically connected to the first electronic component 22 and the second electronic component 24.

As shown in FIG. 2B, an upper end of the package module 29 is ground to remove part of the second packaging layer 244 and the second electronic component 24, and to expose the second electronic component 24.

As shown in FIG. 2C, a component-side carrier 27 is provided, and the second side of the component-side carrier 27 is disposed on the first side of the component section 292. At this time, an external force must be applied to bond the component-side carrier 27 to the package module 29.

In detail, a component-side bonding layer 271 having a release film or other adhesive film is formed on the second side of the component-side carrier 27 by, for example, coating, wherein the component-side bonding layer 271 serves as a sacrificial release layer. The package module 29 is disposed on the second side of the component-side bonding layer 271 via the first side of the component section 292, so as to be sandwiched between the wiring-side carrier 26 and the component-side carrier 27.

As shown in FIG. 2D, the wiring-side carrier 26 and the wiring-side bonding layer 261 are removed, and then an under bump metallurgy (UBM) layer 251 and a plurality of second conductive bumps 252 are formed on the second side of the wiring section 291. The UBM layer 251 may be partially formed in the first insulating layer 211.

The UBM layer 251 can be made of conductive metal material. Each of the second conductive bumps 252 may be formed of solder material or a conductive metal material.

The second conductive bumps 252 are electrically connected to the conductive pillars 212 via the UBM layer 251. Thereby, the second conductive bumps 252 are electrically connected to the first electronic component 22 and the second electronic component 24.

As shown in FIG. 2E, the component-side carrier 27 and the component-side bonding layer 271 are removed.

The electronic structure 2 shown in FIG. 2A to FIG. 2D is a large-layout electronic structure. In other words, the electronic structure 2 includes a plurality of package modules 29, and the manufacturing method shown in FIG. 2A to FIG. 2D is a manufacturing method in which the plurality of package modules 29 are processed simultaneously. Therefore, at this stage, the large-layout electronic structure 2 can be cut into a plurality of individual electronic packages 200.

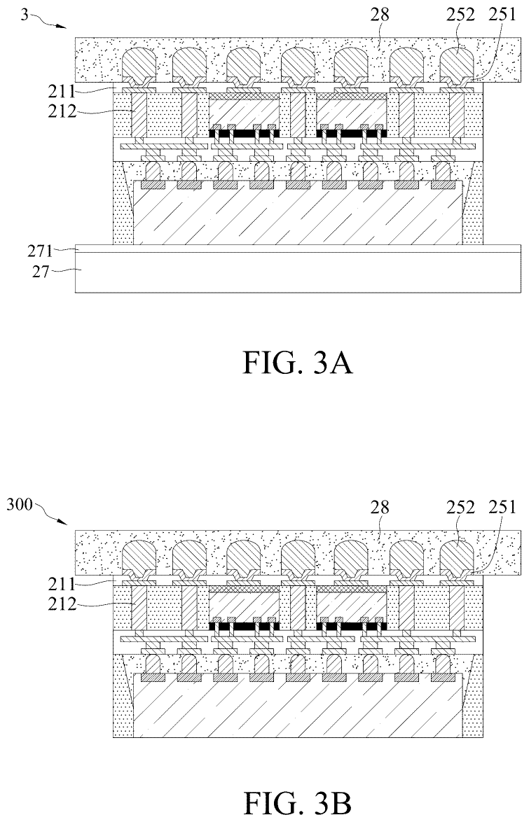

FIG. 3A and FIG. 3B are schematic cross-sectional views illustrating a manufacturing method of an electronic package according to a second embodiment the present disclosure.

First, continuing the manufacturing method shown in FIG. 2A to FIG. 2D, as shown in FIG. 3A, an adhesive layer 28 is formed on the second side of the wiring section 291, so that the adhesive layer 28 covers the second conductive bumps 252.

Next, as shown in FIG. 3B, the component-side carrier 27 and the component-side bonding layer 271 are removed.

The electronic structure 3 shown in FIG. 3A is also a large-layout electronic structure. Therefore, at this stage, the large-layout electronic structure 3 can be cut into a plurality of individual electronic packages 300.

Via process optimization, the electronic structures 2 and 3 of the present disclosure still have the wiring-side carrier 26 when grinding as shown in FIG. 2B. Via the fixing effect of the wiring-side carrier 26, the occurrence of warpage can be reduced. Furthermore, by disposing the component-side carrier 27 after grinding, the warpage of the electronic packages 200 and 300 can be further reduced. In addition, the provision of the adhesive layer 28 can avoid the warping problem caused when the component-side carrier 27 is removed. Therefore, the electronic packages 200 and 300 of the present disclosure are not warp significantly, which is helpful for wafer handling and manufacturing operations.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic structure, comprising:
a package module defined with a wiring section and a component section disposed on the wiring section, wherein the wiring section has a first side and a second side opposite to the first side and includes a first electronic component and a redistribution layer, wherein the component section has a first side and a second side opposite to the first side and includes a second electronic component, and the second side of the component section is disposed on the first side of the wiring section, and wherein, at the same time, the redistribution layer is electrically connected to the first electronic component and the second electronic component; and
a component-side carrier having a first side and a second side opposite to the first side, wherein the second side of the component-side carrier is coupled to on the first side of the component section.

2. The electronic structure of claim 1, wherein a thickness of the component section is greater than a thickness of the wiring section.

3. The electronic structure of claim 1, further comprising:
a wiring-side carrier disposed on the second side of the wiring section.

4. The electronic structure of claim 1, further comprising:
conductive bumps disposed on the second side of the wiring section; and
conductive pillars embedded in the wiring section and electrically connected to the conductive bumps and the redistribution layer.

5. The electronic structure of claim 4, further comprising:
an adhesive layer formed on the second side of the wiring section to cover the conductive bumps.

6. An electronic package, comprising:
a package module defined with a wiring section and a component section disposed on the wiring section, wherein the wiring section has a first side and a second side opposite to the first side and includes a first electronic component and a redistribution layer, wherein the component section has a first side and a second side opposite to the first side and includes a second electronic component, and the second side of the component section is coupled to on the first side of the wiring section, and wherein, at the same time, the redistribution layer is electrically connected to the first electronic component and the second electronic component;
conductive bumps disposed on the second side of the wiring section; and
an adhesive layer formed on the second side of the wiring section to cover the conductive bumps.

7. The electronic package of claim 6, wherein a thickness of the component section is greater than a thickness of the wiring section.

8. A method for manufacturing an electronic package, comprising:
providing a wiring-side carrier and a package module, wherein the package module is defined a wiring section and a component section, each of the wiring-side carrier, the wiring section, and the component section has a first side and a second side opposite to the first side, and the second side of the component section is coupled to the first side of the wiring section;
disposing the package module on the first side of the wiring-side carrier via the second side of the wiring section; and
disposing a component-side carrier having a first side and a second side opposite to the first side on the first side of the component section via the second side of the component-side carrier.

9. The method of claim 8, wherein a thickness of the component section is greater than a thickness of the wiring section.

10. The method of claim 8, wherein an external force is applied to bond the component-side carrier to the package module when the second side of the component-side carrier is disposed on the first side of the component section.

11. The method of claim 8, wherein the wiring section includes a first electronic component and a redistribution layer, the component section includes a second electronic component, and the redistribution layer is electrically connected to the first electronic component and the second electronic component.

12. The method of claim 11, further comprising:
removing the wiring-side carrier; and
forming conductive bumps on the second side of the wiring section.

13. The method of claim 12, further comprising:
forming an adhesive layer on the second side of the wiring section, so that the adhesive layer covers the conductive bumps.

14. The method of claim 13, further comprising:
removing the component-side carrier to form the electronic package.
